(19) United States
(12) Patent Application Publication
(10) Pub. No.: US 2011/0157790 A1
(43) Pub. Date: Jun. 30, 2011

(54) SLIDING-TYPE PORTABLE TERMINAL

(75) Inventor: Hyun KIM, Gyeonggi-do (KR)

(73) Assignee: SAMSUNG ELECTRONICS CO., LTD., Gyeonggi-Do (KR)

(21) Appl. No.: 12/912,858

(22) Filed: Oct. 27, 2010

(30) Foreign Application Priority Data
Dec. 30, 2009 (KR) 10-2009-0134829

(51) Int. Cl. H05K 5/00; B65D 51/00

(52) U.S. Cl. 361/679.01; 220/200

(57) ABSTRACT

Disclosed is a sliding-type portable terminal including: a first housing and a second housing slidably assembled with each other while being in contact with each other; and a sliding plate fixed to the first housing, wherein guide grooves are formed on one surface of the second housing and extend in a movement direction of the second housing, and the sliding plate includes guide members, which extend away from both ends of the sliding plate and slidably engaged with the guide grooves.

### CLAIM OF PRIORITY

This application claims priority under 35 U.S.C. §119(a) to a Korean Patent Application entitled “Sliding-Type Portable Terminal” filed in the Korean Intellectual Property Office on Dec. 30, 2009 and assigned Serial No. 10-2009-134829, the contents of which are incorporated herein by reference.

### BACKGROUND OF THE INVENTION

1. Field of the Invention

The present invention relates to a portable terminal, and more particularly to a sliding-type portable terminal having a pair of housings coupled to face each other in such a manner that one housing can slide on the other housing.

2. Description of the Related Art

In general, a portable terminal refers to a device enabling a user to use a mobile communication function and provide various contents, such as a game, a moving picture, an electronic book, and digital multimedia broadcasting.

Portable terminals are classified into bar-type terminals, flip-type terminals, folder-type terminals, and sliding-type terminals. Because of the compactness and portability of the terminal, the folder-type and sliding-type terminals are mostly used in the current market. With provision of broadcasting and multimedia services using the portable terminal, a large display device with a touch screen in the bar-type terminal is in high demand.

The folder-type or sliding-type terminal has a structure in which a pair of housings are coupled to each other in such a manner that one housing can open/close the other housing. Taking the reliability and durability of the terminal as well as sensibility of the user into consideration, the stable opening/closing operation is necessarily required in the folder-type or sliding-type terminal.

The opening/closing apparatus for a sliding-type portable terminal is disclosed in Korean Patent Registration No. 689,069 (US Patent Publication No. 2008/0058039A1).

In the folder-type or sliding-type terminal, the opening/closing operation of the terminal is not smooth. In order to improve the smooth opening/closing operation of the terminal, the structural stability may suffer. Further, if considering the structural stability only, the thickness of the terminal, or the like, increases which in turn deteriorates the portability of the terminal.

The opening/closing apparatus disclosed in above Korean Patent includes a slide plate 150 fixed to a sub body 120, a main plate 130 fixed to a main body 100, a guide shaft 152, and a guide hole 132, in which the slide plate 150 fixed to the sub body 120 is slidably assembled with the main plate 130, which is fixed to the main body 100. The opening/closing apparatus having the above structure may secure the structural stability, but the guide shaft is required to secure a sufficient diameter in order to guarantee the structural stability, which becomes disadvantageous to the compactness of the terminal. Further, if the movement range of sliding of the terminal increases, the length of the guide shaft also increases. Then, the increased length of the guide shaft makes the guide shaft vulnerable to the bending load. Therefore, the more increased diameter of the guide shaft is disadvantageously required.

### SUMMARY OF THE INVENTION

Accordingly, the present invention has been made to solve the above-stated problems occurring in the prior art and provides additional advantages, by providing a sliding-type portable terminal including an opening/closing apparatus which contributes to the compactness and slimness of the terminal.

Also, the present invention provides a sliding-type portable terminal capable of securing the stable opening/closing operation and structural stability, as well as the compactness and slimness of the terminal.

In accordance with an aspect of the present invention, there is provided a sliding-type portable terminal including: a first housing and a second housing slidably assembled with each other while being in contact with each other; and a sliding plate fixed to the first housing, wherein guide grooves are formed on one surface of the second housing and extend in a movement direction of the second housing, and the sliding plate includes guide members, which extend away from both ends of the sliding plate and slidably engaged with the guide grooves. Both ends of the sliding plate are bent and face each other, and the guide members extend outward from the bent ends of the sliding plate. Further, the bent ends of the sliding plate are inserted in the second housing.

In constructing such a sliding-type portable terminal, the guide member is preferably made from synthetic resin, more particularly, a material having abrasion-resistance and lubricious property, such as polyoxymethylene (POM) or acetal.

In the sliding-type portable terminal having the above construction, the guide members are formed on the sliding plate and guide the sliding of the second housing. The guide members extend away from both ends of the sliding plate and are slidably assembled with the second housing. Therefore, the present invention can achieve a stable assembling structure between the first and second housings. Further, the guide members are made from synthetic resin having excellent mechanical characteristics, such as abrasion-resistance, and a good lubricious property, such as polyoxymethylene (POM) or acetal, so that the sliding of the second housing can be smoothly implemented. Moreover, the sliding-type portable terminal according to the present invention does not employ the guide shaft installed for coupling and sliding of the first and second housings in the opening/closing apparatus of the conventional, so that it can contribute to the compactness of the sliding opening/closing apparatus, ultimately the sliding-type portable terminal.

### BRIEF DESCRIPTION OF THE DRAWINGS

The above and other aspects, features and advantages of the present invention will be more apparent from the following detailed description taken in conjunction with the accompanying drawings, in which:

FIG. 1 is an exploded perspective view illustrating the principle parts of a portable terminal according to an exemplary embodiment of the present invention;

FIG. 2 is a side view illustrating the assembly of a second housing and a sliding plate in the portable terminal of FIG. 1; and

FIG. 3 is an enlarged view illustrating the assembly part of the second housing and the sliding plate in the portable terminal of FIG. 2.

### DETAILED DESCRIPTION OF THE INVENTION

Hereinafter, the first exemplary embodiments of the present invention will be described with reference to the accompanying drawings. For the purposes of clarity and simplicity, a detailed explanation of known related functions and constitutions may be omitted to avoid unnecessarily obscuring the subject matter of the present invention.

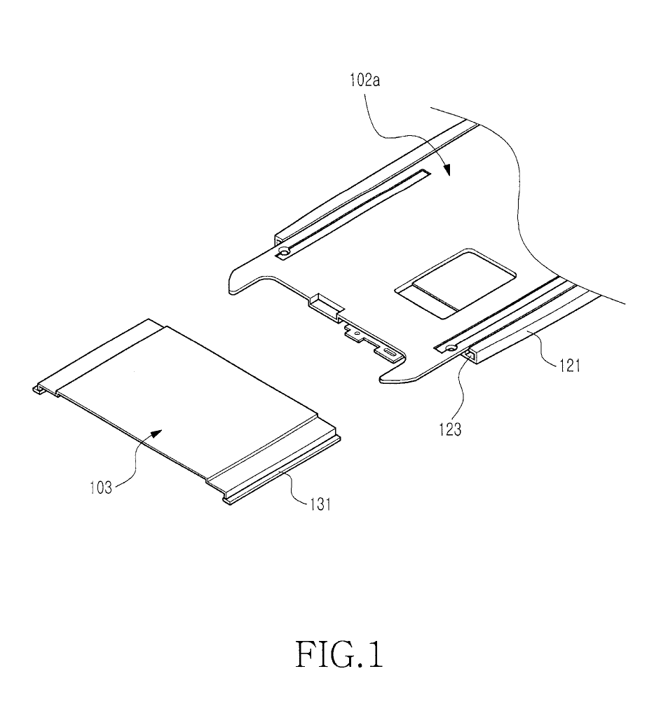

Referring FIGS. 1 to 3, essential components that slidably couple a first housing and a second housing in a sliding-type portable terminal according to an exemplary embodiment of the present invention are shown. As shown, the terminal has a first housing (not shown) and a second housing (not shown) assembled with each other in such a manner that the second housing can slide on the first housing while being in contact with the first housing. The first housing includes a sliding plate 103, and the second housing has guide grooves 123 for slidably holding the sliding plate 103, wherein the guide grooves 123 are formed at one surface of the second housing. FIGS. 1 to 3 show the sliding plate 103 and a lower case 102a located at a back surface of the second housing.

The sliding-type portable terminal according to the present invention further includes an input unit, such as a keypad, on the first housing. The second housing can include an output unit, such as a display device. The input unit installed on the first housing is opened/closed by the sliding of the second housing.

The sliding plate 103 is mounted on one surface of the first housing to guide the sliding of the second housing. The sliding plate 103 includes guide members 131 formed on both ends of the sliding plate 103. The guide members 131 extend away from each other from both ends of the sliding plate 103. Both ends of the sliding plate 103 are bent to face each other, and the guide members 103 extend from the ends of the bent portions of the sliding plate 103.

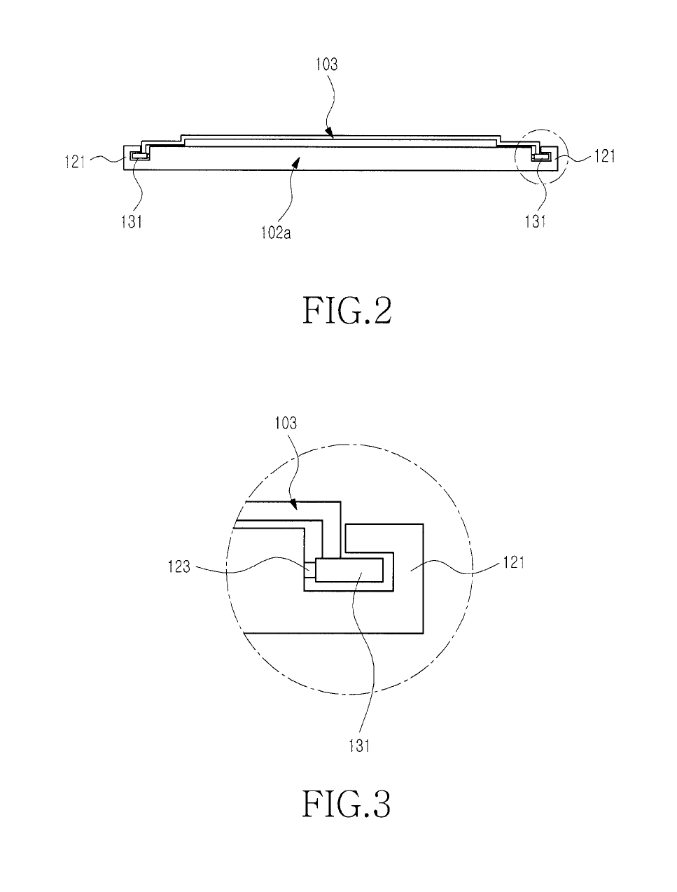

The lower case 102a of the second housing has guide channel members 121 formed at both ends thereof, and the guide groove 123 is formed inside of each of the guide channel member 121 such that each of the guide channel member 121 surrounds the guide groove 123. The guide groove 123 extends along a sliding direction of the second housing. Referring to FIGS. 2 and 3, the guide groove 123 is formed in an “L” shape.

Further, as shown in FIG. 1, one end of the guide groove 123 is opened so that the guide member 131 is inserted into the guide groove 123 from one end of the guide groove and engaged with the guide groove 123. As soon as the guide member 131 is engaged with the guide groove 123, the bent portion of the sliding plate 103 is inserted through an internal opening of the second housing.

A separately manufactured upper case (not shown) may be assembled with the loser case 102a to complete the second housing. In this case, when the lower case 102a has been assembled with the upper case, the opened end of the guide groove 123 is closed. Therefore, the sliding plate 103 is slidably held by the second housing in a state.

Therefore, the sliding plate 103 is assembled with the second housing in a shape in which the guide member 131 is surrounded by the guide channel member 121, to guide the sliding of the second housing.

In order to relieve friction and noise associated with the sliding of the second housing, lubricant oil can be applied inside of the guide groove 123. Alternatively, the lower case 102a or the sliding plate 103 can be made from synthetic resin for reducing friction and noise. However, in order to prevent damage due to the shock, or the like, it is preferable to manufacture the lower case 102a or the sliding plate 103 with a metallic material.

Further, in order to reduce friction and noise according to the sliding of the second housing, the guide member 131 may be preferably made of synthetic resin, such as polyoxymethylene (POM) or acetal. Also, another part of the sliding plate 103 or the lower case 102a can be manufactured of a metallic material. The POM or acetal not only has excellent mechanical characteristics, such as abrasion resistance, but also has a good lubricious property so that it can provide a stable assembly force in the sliding assembly structure and contribute to reducing the friction and noise.

The guide member 131 made of the synthetic resin can be formed by coating surfaces of both ends of the sliding plate 103 or double injection molding.

As described above, the sliding plate 103 is slidably assembled with the guide grooves 123 formed on the second housing so that the sliding-type portable terminal can achieve a simple and stable assembling structure.

While the present invention has been shown and described with reference to certain exemplary embodiments and drawings thereof, it will be understood by those skilled in the art that various changes in form and details may be made therein without departing from the spirit and scope of the invention as defined by the appended claims.

For example, even though not shown in the embodiment of the present invention, an elastic member may be formed on the sliding plate 103 and the lower case 102a by which both ends of the elastic member are supported, so that the elastic member provides a driving force that slides the second housing. It is preferred that the elastic member provides elastic force applied to separate both ends of the elastic member away from each other. Further, a point where both ends of the elastic member are most adjacent to each other is set within the sliding range of the second housing. In this case, at the point where both ends of the elastic member are most adjacent, the elastic member applies a driving force pushing the second housing to close the input device mounted on the first housing toward one side and a driving force pushing the second housing to open the input device toward another side.

What is claimed is:

1. A sliding-type portable terminal, comprising:
a first housing and a second housing slidably assembled with each other; and
a sliding plate coupled to the first housing, wherein guide grooves are formed on one surface of the second housing and extend in a movement direction of the second housing, and the sliding plate having guide members, which extend away from both ends of the sliding plate and slidably engaged with the guide grooves.

2. The sliding-type portable terminal as claimed in claim 1, wherein both ends of the sliding plate are bent and face each other, and the guide members extend outward from the bent ends of the sliding plate.

3. The sliding-type portable terminal as claimed in claim 2, wherein the bent ends of the sliding plate are slidably inserted in the second housing.

4. The sliding-type portable terminal as claimed in claim 1, wherein the guide member is made from synthetic resin.

5. The sliding-type portable terminal as claimed in claim 4, wherein the synthetic resin comprises polyoxymethylene (POM) or acetal.

6. The sliding-type portable terminal as claimed in claim 1, wherein the sliding plate and the second housing are made from metallic materials.

7. The sliding-type portable terminal as claimed in claim 1, wherein the first housing further includes an input unit.

8. The sliding-type portable terminal as claimed in claim 7, wherein the input unit is selectively opened and closed by the sliding movement of the second housing.

9. The sliding-type portable terminal as claimed in claim 1, wherein the second housing further includes an output unit.

10. The sliding-type portable terminal as claimed in claim 9, wherein the output unit comprises a display.

11. The sliding-type portable terminal as claimed in claim 1, wherein the second housing comprises a lower case having guide channel members formed at both ends thereof.

12. The sliding-type portable terminal as claimed in claim 1, wherein the sliding plate and the lower case are located at a back surface of the second housing.
